(19) United States
(12) Patent Application Publication
(10) Pub. No.: US 2024/0147763 A1
(43) Pub. Date: May 2, 2024

(54) THIN FILM TRANSISTOR ARRAY SUBSTATE AND DISPLAY DEVICE INCLUDING THE SAME

(71) Applicant: LG Display Co., Ltd., Seoul (KR)

(72) Inventor: Jeong Yeop LEE, Paju-si (KR)

(73) Assignee: LG Display Co., Ltd., Seoul (KR)

(21) Appl. No.: 18/467,249

(22) Filed: Sep. 14, 2023

(30) Foreign Application Priority Data
Oct. 28, 2022 (KR) 10-2022-0141369

(51) Int. Cl. H10K 59/121; H10K 59/126

(52) U.S. Cl. CPC H10K 59/1213; H10K 59/126

(57) ABSTRACT

A thin film transistor array substrate includes a substrate including an active area and a non-active area, a first thin film transistor disposed on the substrate, and a first light shielding pattern between the substrate and the first thin film transistor, the first thin film transistor includes a first oxide semiconductor pattern disposed on the substrate, a first gate electrode, a first gate insulating layer interposed between the first oxide semiconductor pattern and the first gate electrode, a first source electrode, and a first drain electrode, the first light shielding pattern electrically connected to one of the first source electrode and the first drain electrode is disposed under the first oxide semiconductor pattern, and the first oxide semiconductor pattern includes a first portion configured to form a first parasitic capacitance, together with the first gate electrode, and a second portion configured to form a second parasitic capacitance different from the first parasitic capacitance, together with the first gate electrode.

This application claims the priority of Korean Patent Application No. 10-2022-0141369, filed on Oct. 28, 2022, which is hereby incorporated by reference in its entirety.

### BACKGROUND

### Field of the Disclosure

The present disclosure relates to an array substrate of a thin film transistor including an oxide semiconductor pattern, and more particularly to a thin film transistor array substrate enabling a thin film transistor disposed on a substrate to achieve an enhancement in low-grayscale expression and blockage of leakage current, and a display device including the same. In particular, the present disclosure relates to a display device in which a driving thin film transistor configured to drive a pixel has a widened grayscale expression range and an increased s-factor value, thereby being capable of realizing a rapid on/off operation while achieving grayscale expression in a wide range.

### Description of the Background

Recently, in accordance with advances in multimedia, the importance of a flat display device has increased. To cope with such a situation, flat display devices such as a liquid crystal display device, a plasma display device, an organic light emitting display device, etc. are being commercialized. Among such flat display devices, the organic light emitting display device is currently mainly used in that the display device has fast response time, high luminance, and a wide viewing angle.

In such an organic light emitting device, a plurality of pixels is disposed in a matrix, and each of the pixels includes a light emitting device part represented by an organic light emitting layer and a pixel circuit part represented by a thin film transistor (hereinafter referred to as a “TFT”). The pixel circuit part includes a driving TFT configured to operate an organic light emitting element through supply of drive current and a switching TFT configured to supply a gate signal to the driving TFT.

In addition, a gate driving circuit part configured to provide a gate signal to each pixel may be disposed in a non-active area of the organic light emitting display device.

In connection with this, the present disclosure relates to an array substrate of a thin film transistor disposed at a pixel, in particular, a pixel circuit part of a sub-pixel, and configured to block leakage current in an off state and to achieve free grayscale expression even at low gray levels, and a display device including the same.

### SUMMARY

Accordingly, the present disclosure is directed to a thin film transistor array substrate and a display device including the same that substantially obviate one or more problems due to limitations and disadvantages described above.

The present disclosure is to provide a thin film transistor disposed within a pixel and configured to exhibit a high effect of blocking leakage current in an off state and to achieve grayscale expression within a wide range.

The present disclosure is also to provide sub-thin film transistors included in one thin film transistor while having threshold voltages adjusted to be different from one another, thereby providing a driving thin film transistor capable of achieving free grayscale expression even at low gray levels while using an oxide semiconductor pattern as an active layer thereof.

Additional advantages and features of the present disclosure will be set forth in part in the description which follows and in part will become apparent to those having ordinary skill in the art upon examination of the following or may be learned from practice of the disclosure. Other advantages of the present disclosure may be realized and attained by the structure particularly pointed out in the written description and claims hereof as well as the appended drawings.

To achieve these and other advantages and in accordance with the present disclosure, as embodied and broadly described herein, a thin film transistor array substrate includes a substrate including an active area and a non-active area disposed around the active area, a first thin film transistor disposed on the substrate, and a first light shielding pattern between the substrate and the first thin film transistor, wherein the first thin film transistor includes a first oxide semiconductor pattern disposed on the substrate, a first gate electrode, a first gate insulating layer interposed between the first oxide semiconductor pattern and the first gate electrode, a first source electrode, and a first drain electrode, wherein the first light shielding pattern is electrically connected to one of the first source electrode and the first drain electrode and is disposed under the first oxide semiconductor pattern, wherein the first oxide semiconductor pattern includes a first portion configured to form a first parasitic capacitance, together with the first gate electrode, and a second portion configured to form a second parasitic capacitance, together with the first gate electrode, and wherein the first parasitic capacitance and the second parasitic capacitance are different from each other.

The first portion of the first oxide semiconductor pattern may include a first protrusion protruding toward the first gate electrode.

The first portion of the first oxide semiconductor pattern may include a first sink recessed to be spaced away from the first gate electrode.

The first oxide semiconductor pattern may include a first source region connected to the first source electrode, a first drain region connected to the first drain electrode, and a first channel region disposed between the first source region and the first drain region. Lengths of the first protrusion and the first sink may be equal to or greater than a length of the first channel region

The first protrusion or the first sink of the first oxide semiconductor pattern may correspond to the first channel region.

A buffer layer may be further formed between the first oxide semiconductor pattern and the first light shielding pattern. The buffer layer may include a second protrusion protruding toward the first gate electrode or a second sink recessed to be spaced away from the first gate electrode.

The first protrusion and the first sink may be formed along a curvature of an upper surface of the buffer layer.

Each of the first protrusion or the first sink may be disposed in a number of at least one in a width direction of the first channel region.

When a vertical distance from the first protrusion to the first gate electrode is a first vertical distance (D1), and a vertical distance from the first oxide semiconductor pattern, except for the first protrusion, to the first gate electrode is a second vertical distance (D2), the second vertical distance (D2) may be greater than the first vertical distance (D1).

When a vertical distance from the first sink to the first gate electrode is a second vertical distance (D2), and a vertical distance from the first oxide semiconductor pattern, except for the first sink, to the first gate electrode is a first vertical distance (D1), the second vertical distance (D2) may be greater than the first vertical distance (D1).

The first thin film transistor may be a driving thin film transistor configured to drive a pixel disposed in the active area.

A parasitic capacitance formed between the first light shielding pattern and the first oxide semiconductor pattern may be greater than a parasitic capacitance formed between the first gate electrode and the first oxide semiconductor pattern.

The first thin film transistor may include a first sub-first thin film transistor and a second sub-first thin film transistor. The first sub-first thin film transistor may include the first portion of the first oxide semiconductor pattern, the first gate electrode, the first source electrode, and the first drain electrode. The second sub-first thin film transistor may include the second portion of the first oxide semiconductor pattern, the first gate electrode, the first source electrode, and the first drain electrode. A threshold voltage of the first sub-first thin film transistor may be different from a threshold voltage of the second sub-first thin film transistor.

In another aspect of the present disclosure, there is provided a display device including the thin film transistor array substrate, and a light emitting device part disposed on the substrate, the light emitting device part including a first electrode connected to the first drain electrode, a second electrode corresponding to the first electrode, and a light emitting layer disposed between the first electrode and the second electrode.

The present disclosure is not limited to the above-described features, and other features of the present disclosure not yet described will be more clearly understood by those skilled in the art from the following detailed description.

### BRIEF DESCRIPTION OF THE DRAWINGS

The accompanying drawings, which are included to provide a further understanding of the present disclosure and are incorporated in and constitute a part of this application, illustrate aspect(s) of the disclosure and along with the description serve to explain the principle of the disclosure. In the drawings:

FIG. 1 is a schematic block diagram of a display device according to an exemplary aspect of the present disclosure;

FIG. 2 is a schematic block diagram of a sub-pixel in the display device according to the exemplary aspect of the present disclosure;

FIG. 3 is a circuit diagram of one sub-pixel of the display device according to the exemplary aspect of the present disclosure;

FIG. 4 is a cross-sectional view showing one thin film transistor disposed at a gate driving circuit part in a non-active area, a driving thin film transistor DT disposed in an active area while including a gate insulating layer including a sink, a switching thin film transistor, and a storage capacitor in accordance with a first aspect of the present disclosure;

FIG. 5A is an enlarged plan view in which only the driving thin film transistor shown in FIG. 4 is enlarged;

FIG. 5B is a perspective view showing inclusion of a protrusion in a portion of an upper insulating layer in accordance with the first aspect of the present disclosure;

FIG. 5C is a cross-sectional view of a portion of the driving thin film transistor taken along line E-E′ in FIG. 5A;

FIG. 5D is a cross-sectional view of a portion of the driving thin film transistor taken along line F-F′ in FIG. 5A;

FIG. 5E is a cross-sectional view of a portion of the driving thin film transistor taken along line G-G′ in FIG. 5A;

FIG. 6 is graphs depicting I-V curves of sub-thin film transistors created in the driving thin film transistor of the aspect of the present disclosure and synthesis relations thereof;

FIG. 7A is a perspective view of an upper insulating layer including a sink in a driving thin film transistor in accordance with another aspect of the present disclosure;

FIG. 7B is an enlarged plan view in which only the driving thin film transistor and a switching thin film transistor are enlarged;

FIG. 7C is a cross-sectional view of a portion of the driving thin film transistor according to the other aspect of the present disclosure shown in FIG. 7B taken along line E-E′ in FIG. 5A;

FIG. 7D is a cross-sectional view of a portion of the driving thin film transistor according to the other aspect of the present disclosure shown in FIG. 7B taken along line F-F′ in FIG. 5A; and

FIG. 7E is a cross-sectional view of a portion of the driving thin film transistor according to the other aspect of the present disclosure shown in FIG. 7B taken along line G-G′ in FIG. 5A.

### DETAILED DESCRIPTION

Advantages and features of the present disclosure and methods for achieving the same will be made clear from aspects described below in detail with reference to the accompanying drawings. The present disclosure may, however, be embodied in many different forms, and should not be construed as being limited to the aspects set forth herein. Rather, these aspects are provided so that this disclosure will be thorough and complete, and will fully convey the scope of the disclosure to those skilled in the art.

In the drawings for explaining the exemplary aspects of the present disclosure, for example, the illustrated shape, size, ratio, angle, and number are given by way of example, and thus, are not limited to the disclosure of the present disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear. The terms “comprises”, “includes”, and/or “has”, used in this specification, do not preclude the presence or addition of other elements unless used along with the term “only”. The singular forms are intended to include the plural forms as well, unless the context clearly indicates otherwise.

In the interpretation of constituent elements included in the various aspects of the present disclosure, the constituent elements are interpreted as including an error range even if there is no explicit description thereof.

In the description of the various aspects of the present disclosure, when describing positional relationships, for example, when the positional relationship between two parts is described using “on”, “above”, “below”, “next to”, or the like, one or more other parts may be located between the two parts unless the term “directly” or “closely” is used.

In the description of the various aspects of the present disclosure, when describing temporal relationships, for example, when the temporal relationship between two actions is described using “after”, “subsequently”, “next”, “before”, or the like, the actions may not occur in succession unless the term “directly” or “just” is used therewith.

It may be understood that, although the terms “first”, “second”, etc. may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless mentioned otherwise.

The respective features of the various aspects of the present disclosure may be partially or entirely coupled to and combined with each other, and various technical linkages and modes of operation thereof are possible. These various aspects may be performed independently of each other, or may be performed in association with each other.

Hereinafter, a display device according to an exemplary aspect of the present disclosure will be described in detail with reference to the accompanying drawings.

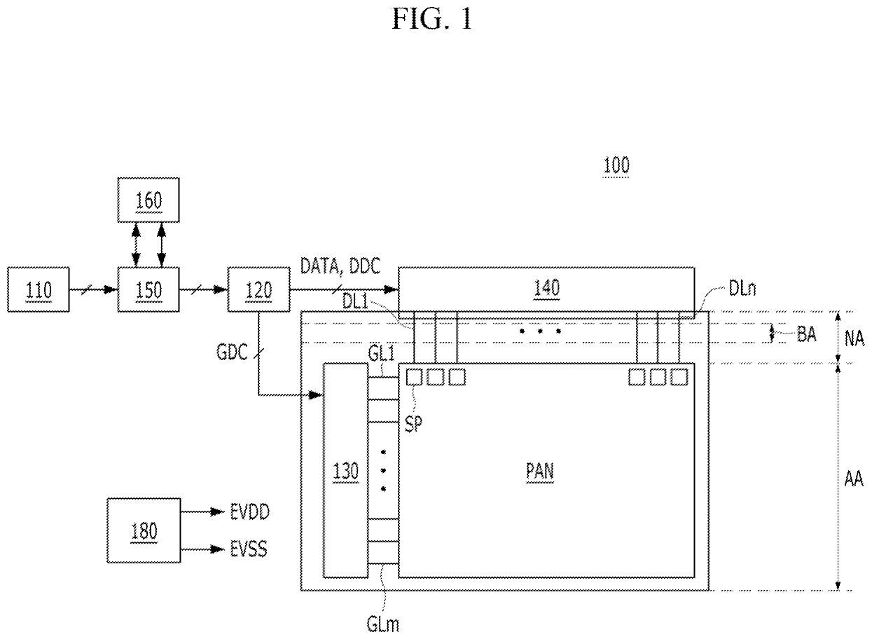

FIG. 1 is a schematic block diagram of a display device 100 according to the exemplary aspect of the present disclosure.

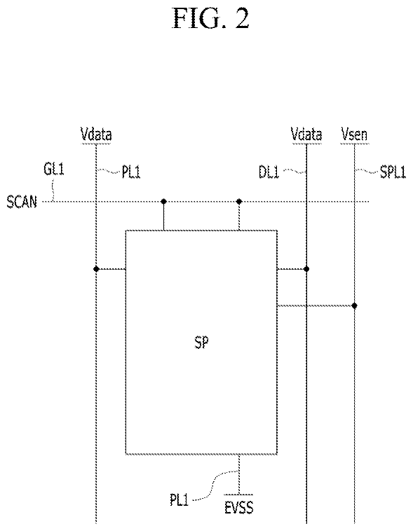

FIG. 2 is a schematic block diagram of a sub-pixel SP shown in FIG. 1.

As shown in FIG. 1, the display device 100 includes an image processor 110, a degradation compensator 150, a memory 160, a timing controller 120, a data driver 140, a power supply 180, a gate driver 130, and a display panel PAN formed with the gate driver 130 therein. A non-active area NA of the display panel PAN may include a bending area BA. The display panel PAN may be folded in the bending area BA and, as such, may reduce a bezel.

The image processor 110 outputs driving signals for driving various devices, together with image data supplied from an exterior thereof.

The degradation compensator 150 modulates input image data Idata of each sub-pixel SP of a current frame based on a sensing voltage Vsen supplied from the data driver 140, and then supplies the modulated image data, that is, data Mdata, to the timing controller 120.

The timing controller 120 generates and outputs a gate timing control signal GDC for control of operation timing of the gate driver 130 and a data timing control signal DDC for control of operation timing of the data driver 140 based on a drive signal input from the image processor 110 thereto.

The gate driver 130 outputs a scan signal to the display panel PAN in response to the gate timing control signal GDC supplied from the timing controller 120. The gate driver 130 outputs the scan signal through a plurality of gate lines GL1 to GLm. In particular, the gate driver 130 may be configured to have a gate-in-panel (GIP) structure in which a thin film transistor is stacked on a substrate in the display device 100 which may be an organic electroluminescent display device. The GIP may include a plurality of circuits such as a shift register, a level shifter, etc.

The data driver 140 outputs a data voltage to the display panel PAN in response to the data timing control signal DDC input from the timing controller 120 thereto. The data driver 140 outputs the data voltage through a plurality of data lines DL1 to DLn.

The power supply 180 outputs a high-level drive voltage EVDD, a low-level drive voltage EVSS, etc., and supplies the output voltages EVDD, EVSS, etc. to the display panel PAN. The high-level drive voltage EVDD and the low-level drive voltage EVSS are supplied to the display panel PAN through power lines.

The display panel PAN displays an image, corresponding to the data voltage and the scan signal respectively supplied from the data driver 140 and the gate driver 130, which may be disposed in the non-active area NA, and power supplied from the power supply 180.

An active area AA of the display panel PAN is constituted by a plurality of sub-pixels SP and, as such, displays an actual image. The sub-pixels SP include a red (R) sub-pixel, a green (G) sub-pixel, and a blue (B) sub-pixel, or include a white (W) sub-pixel, a red (R) sub-pixel, a green (G) sub-pixel, and a blue (B) sub-pixel. In this case, the W, R, G, and B sub-pixels SP may be formed to have the same area or may be formed to have different areas, respectively.

The memory 160 not only stores a look-up table for degradation compensation gains, but also stores a degradation compensation time point of an organic light emitting element of each sub-pixel SP. In this case, the degradation compensation time point of the organic light emitting element may be the number of times when an organic light emitting display panel is driven or the time for which the organic light emitting display panel is driven.

Meanwhile, as shown in FIG. 2, each sub-pixel SP may be connected to one gate line, for example, the gate line GL1, one data line, for example, the data line DL1, one sensing voltage read-out line, for example, a sensing voltage read-out line SRL1, and one power line, for example, a power line PL1. The numbers of transistors and capacitors of the sub-pixel SP and the driving method of the sub-pixel SP are determined in accordance with a circuit configuration of the sub-pixel SP.

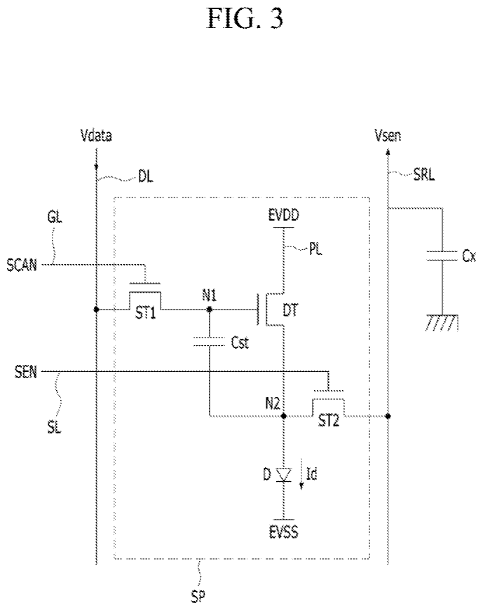

FIG. 3 is a circuit diagram of one sub-pixel SP of the display device 100 according to the exemplary aspect of the present disclosure.

As shown in FIG. 3, the display device 100 according to the exemplary aspect of the present disclosure includes a gate line GL, a data line DL, a power line PL, and a sensing line SL intersecting one another, thereby defining a sub-pixel SP, and includes a driving thin film transistor DT, a light emitting element D, a storage capacitor Cst, a first switching thin film transistor ST1, and a second switching thin film transistor ST2 at the sub-pixel SP.

The light emitting element D may include an anode connected to a second node N2, a cathode connected to an input terminal for a low-level drive voltage EVSS, and an organic light emitting layer disposed between the anode and the cathode.

The driving thin film transistor DT controls current Id flowing through the light emitting element D in accordance with a gate-source voltage Vgs thereof. The driving thin film transistor DT includes a gate electrode connected to a first node N1, a drain electrode connected to the power line PL, to receive a high-level drive voltage EVDD, and a source electrode connected to the second node N2.

The storage capacitor Cst is connected between the first node N1 and the second node N2.

When the display panel PAN is driven, the first switching thin film transistor ST1 applies a data voltage Vdata charged in the data line DL to the first node N1 in response to a scan signal SCAN, thereby turning on the driving thin film transistor DT. In this case, the first switching thin film transistor ST1 includes a gate electrode connected to the gate line GL, to receive the scan signal SCAN, a drain electrode connected to the data line DL, to receive the data voltage Vdata, and a source electrode connected to the first node N1.

The second switching thin film transistor ST2 stores a source voltage of the second node N2 in a sensing capacitor Cx of a sensing voltage read-out line SRL by switching current between the second node N2 and the sensing voltage read-out line SRL in response to a sensing signal SEN. The second switching thin film transistor ST2 resets a source voltage of the driving thin film transistor DT to an initialization voltage Vpre by switching current between the second node N2 and the sensing voltage read-out line SRL in response to the sensing signal SEN when the display panel PAN is driven. In this case, in the second switching thin film transistor ST2, a gate electrode thereof is connected to the sensing line SL, a drain electrode thereof is connected to the second node N2, and a source electrode thereof is connected to the sensing voltage read-out line SRL.

Meanwhile, although a display device having a 3T1C structure including three thin film transistors and one storage capacitor has been illustrated and described, the display device of the present disclosure may be applied to various pixel structures such as 4T1C, 5T1C, 6T1C, 7T1C, and 8T1C without being limited to the above-described structure.

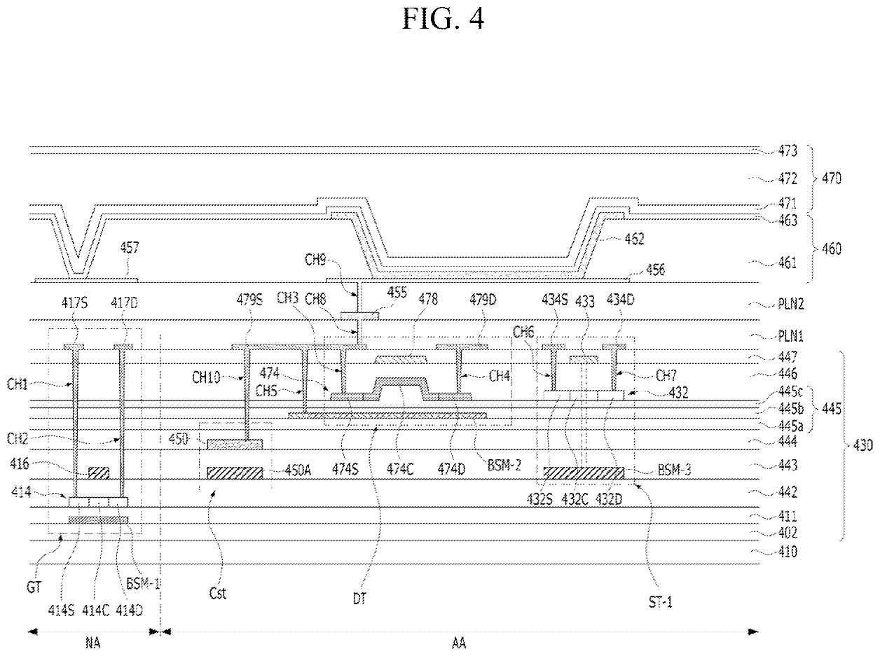

Meanwhile, FIG. 4 is a cross-sectional view showing one thin film transistor GT for a gate driving circuit, which is a representative thin film transistor disposed in a non-active area NA, in particular, a GIP area, while including a polycrystalline semiconductor pattern, a driving thin film transistor DT disposed in a sub-pixel in an active area AA while including an oxide semiconductor pattern configured to drive a light emitting element, a first switching thin film transistor ST-1 including an oxide semiconductor pattern, and a storage capacitor Cst in accordance with a first aspect of the present disclosure.

As shown in FIG. 4, the driving thin film transistor DT and the first switching thin film transistor ST-1 are disposed in a sub-pixel on a substrate 410. Although the driving thin film transistor DT and only one switching thin film transistor ST-1 are illustrated in FIG. 4, this illustration is only for convenience of description, and a plurality of switching thin film transistors may actually be disposed on the substrate 410.

In addition, a plurality of thin film transistors GT for a gate driving circuit constituting a gate driver may be disposed in the non-active area NA on the substrate 410, in particular, the GIP area. The thin film transistor GT for the gate driving circuit, which will be referred to as a “gate driving thin film transistor GT”, may use a polycrystalline semiconductor pattern as an active layer thereof.

Although the case in which the gate driving thin film transistor GT including the polycrystalline semiconductor pattern is disposed in the non-active area NA is described in the first aspect, a switching thin film transistor having the same structure as that of the gate driving thin film transistor GT may be disposed in the sub-pixel.

Of course, the gate driving thin film transistor GT disposed in the non-active area NA and the switching thin film transistor disposed in the active area AA may have different configurations, like an N-type thin film transistor and a P-type thin film transistor, because kinds of impurities implemented therein are different.

Meanwhile, the plurality of thin film transistors disposed in the gate driver may constitute a CMOS configuration in which a thin film transistor for a gate driving circuit including a polycrystalline semiconductor pattern and a switching thin film transistor including an oxide semiconductor pattern are paired.

The following description will be given in conjunction with an example in which a thin film transistor for a gate driving circuit using a polycrystalline semiconductor pattern as an active layer thereof is disposed in the non-active area NA.

The gate driving thin film transistor GT includes a polycrystalline semiconductor pattern 414 disposed on a lower buffer layer 402/411 formed on the substrate 410, a first gate insulating layer 442 configured to insulate the polycrystalline semiconductor pattern 414, a first gate electrode 416 disposed on the first gate insulating layer 442 while overlapping with the polycrystalline semiconductor pattern 414, a plurality of insulating layers formed on the first gate electrode 416, and a first source electrode 417S and a first drain electrode 417D disposed on the plurality of insulating layers.

The substrate 410 may be constituted by a multilayer structure in which an organic layer and an inorganic layer are alternately stacked. For example, the substrate 410 may have a multilayer structure in which an organic layer of, for example, polyimide, and an inorganic layer of, for example, silicon oxide (SiO₂), are alternately stacked.

The lower buffer layer 402/411 is formed on the substrate 410. The lower buffer layer 402/411 functions to prevent moisture, etc. from penetrating from the outside. The lower buffer layer 402/411 may be formed by depositing an inorganic insulating layer of, for example, silicon oxide (SiO₂), in a number of at least one layer.

The lower buffer layer 402/411 may include a plurality of layers including a first lower buffer layer 402 and a second lower buffer layer 411. In addition, a first light shielding pattern BSM-1 configured to protect the polycrystalline semiconductor pattern 414 from external light may be provided on the first lower buffer layer 402. The first light shielding pattern BSM-1 may be disposed between the first lower buffer layer 402 and the second lower buffer layer 411.

The polycrystalline semiconductor pattern 414 is formed on the lower buffer layer 402/411. The polycrystalline semiconductor pattern 414 is used as the active layer of the thin film transistor. The polycrystalline semiconductor pattern 414 includes a first channel region 414C, and a first source region 414S and a first drain region 414D facing each other under the condition that the first channel region 414C is interposed therebetween.

The polycrystalline semiconductor pattern 414 is insulated by the first gate insulating layer 442. The first gate insulating layer 442 is formed by depositing an inorganic insulating layer of, for example, silicon oxide (SiO₂), in a number of at least one layer on the entire surface of the substrate 410 formed with the polycrystalline semiconductor pattern 414. The first gate insulating layer 442 protects and insulates the polycrystalline semiconductor pattern 414 from the outside.

The first gate electrode 416 overlapping with the first channel region 414C of the polycrystalline semiconductor pattern 414 is formed on the first gate insulating layer 442.

The first gate electrode 416 may be made of a metal material. For example, the first gate electrode 416 may take the form of a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

A plurality of insulating layers may be formed between the first gate electrode 416 and each of the first source electrode 417S and the first drain electrode 417D.

Referring to FIG. 4, the plurality of insulating layers may include a first interlayer insulating layer 443 contacting an upper surface of the first gate electrode 416, a second interlayer insulating layer 444, an upper buffer layer 445, a second gate insulating layer 446, and a third interlayer insulating layer 447 sequentially stacked on the first interlayer insulating layer 443 in this order.

The first source electrode 417S and the first drain electrode 417D are disposed on the third interlayer insulating layer 447. The first source electrode 417S and the first drain electrode 417D are connected to the polycrystalline semiconductor pattern 414 through a first contact hole CH1 and a second contact hole CH2, respectively. The first contact hole CH1 and the second contact hole CH2 extend through the first gate insulating layer 442, the first interlayer insulating layer 443, the second interlayer insulating layer 444, the upper buffer layer 445, the second gate insulating layer 446, and the third interlayer insulating layer 447, thereby exposing the first source region 414S and the first drain region 414D of the polycrystalline semiconductor pattern 414, respectively.

Meanwhile, the driving thin film transistor DT, the first switching thin film transistor ST-1, and the storage capacitor Cst are disposed at the sub-pixel in an active area AA.

In the first aspect, each of the driving thin film transistor DT and the first switching thin film transistor ST-1 uses an oxide semiconductor material as an active layer thereof.

The driving thin film transistor DT includes a first oxide semiconductor pattern 474, and a second gate electrode 478, a second source electrode 479S, and a second drain electrode 479D overlapping with the first oxide semiconductor pattern 474.

The oxide semiconductor may be made of an oxide of a metal such as zinc (Zn), indium (In), gallium (Ga), tin (Sn), titanium (Ti), or the like, or a combination of a metal such as zinc (Zn), indium (In), gallium (Ga), tin (Sn), titanium (Ti), or the like and an oxide thereof. More specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), or the like.

Generally, a polycrystalline semiconductor pattern advantageous in terms of high-speed operation is used as an active layer of a driving thin film transistor. In the case of a driving thin film transistor including a polycrystalline semiconductor pattern, there may be a problem in terms of power consumption in that leakage current is generated in an off state of the driving thin film transistor. In particular, the problem of generation of leakage current in an off state of the driving thin film transistor may be severe when the display device is driven at a low speed to display a still image such as a document screen. To this end, in the first aspect of the present disclosure, a driving thin film transistor using, as an active layer thereof, an oxide semiconductor pattern advantageous in preventing generation of leakage current while being capable of adjusting a threshold voltage, thereby achieving free grayscale expression within a wide range, is proposed.

However, when the thin film transistor uses an oxide semiconductor pattern as an active layer thereof, a current fluctuation value with respect to a voltage fluctuation value may be great due to characteristics of an oxide semiconductor material and, as such, failure may frequently occur in a low-grayscale range in which precise current control is required. In addition, the driving thin film transistor using the oxide semiconductor pattern as the active layer thereof has a high threshold voltage and, as such, exhibits a limitation in grayscale expression.

Therefore, in accordance with the first aspect of the present disclosure, a driving thin film transistor in which fluctuation in current is relatively insensitive to fluctuation in a voltage applied to a gate electrode, and a threshold voltage is adjustable to achieve grayscale expression even at low gray levels is proposed.

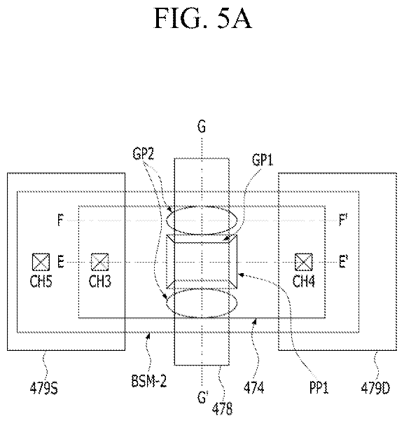

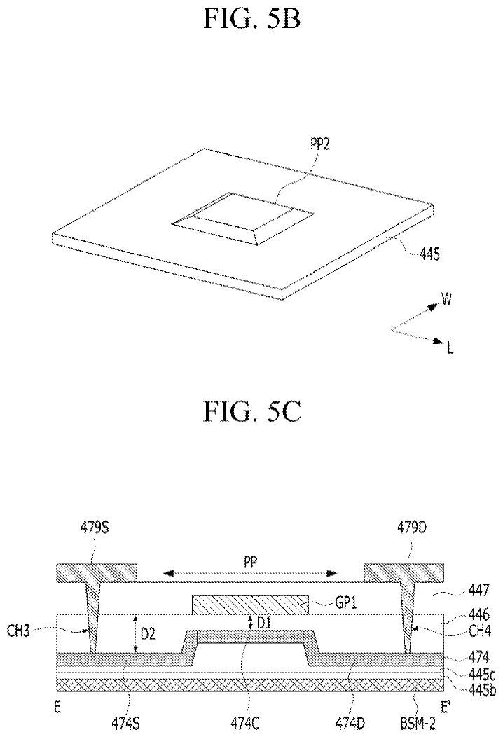

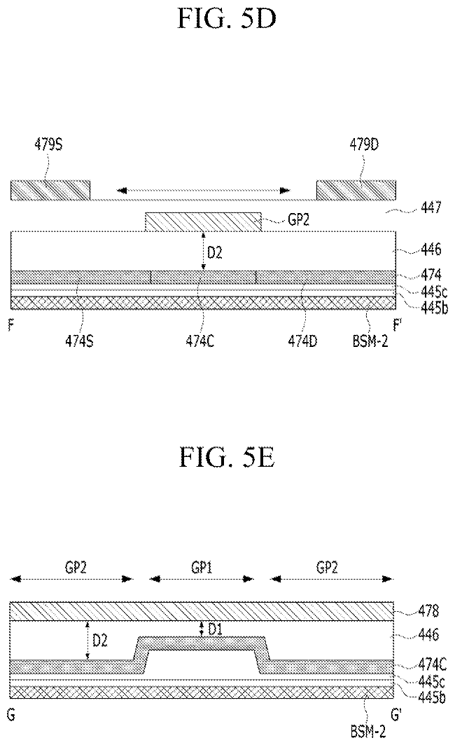

A structure of the driving thin film transistor according to the first aspect of the present disclosure will be described with reference to FIGS. 4 to 5E.

FIG. 5A is a plan view of the driving thin film transistor DT shown in FIG. 4, viewed from the top side.

FIG. 5B is a perspective view showing a structure of the upper buffer layer 445 of the driving thin film transistor DT. FIGS. 5C, 5D, and 5E show cross-sectional structures of FIG. 5A taken along lines E-E′, F-F′, and G-G′, respectively.

The driving thin film transistor DT includes the first oxide semiconductor pattern 474, which is disposed on the upper buffer layer 445, the second gate electrode 478, which is disposed over the first oxide semiconductor pattern 474 while overlapping with the first oxide semiconductor pattern 474, the second gate insulating layer 446, which is interposed between the first oxide semiconductor pattern 474 and the second gate electrode 478, the third interlayer insulating layer 447 covering the second gate electrode 478, a second light shielding pattern BSM-2 disposed under the first oxide semiconductor pattern 474 while overlapping with the first oxide semiconductor pattern 474, and the second source electrode 479S and the second drain electrode 479D, which are disposed on the third interlayer insulating layer 447.

The first oxide semiconductor pattern 474 includes a second channel region 474C, and a second source region 474S and a second drain region 474D respectively formed at opposite ends of the second channel region 474C.

In particular, the second light shielding pattern BSM-2 is connected to the second source electrode 479S via a fifth contact hole CH5.

In addition, the upper buffer layer 445 includes at least two portions respectively having different thicknesses and, as such, the first oxide semiconductor pattern 474 deposited on the upper buffer layer 445 includes at least two portions respectively having different vertical distances from the second gate electrode 478.

That is, referring to FIG. 5B, the upper buffer layer 445 includes, at a portion thereof, a protrusion protruding toward the second gate electrode 478.

Referring to FIG. 5A, the protrusion may be formed in the second channel region 474C where the first oxide semiconductor pattern 474 and the second gate electrode 478 overlap with each other. The protrusion may be formed in a number of at least one in a width direction of the channel region 474C.

As the upper buffer layer 445 includes the protrusion, the first oxide semiconductor pattern 474 deposited on an upper surface of the upper buffer layer 445 also includes a protrusion. To distinguish the protrusions from each other, for convenience of description, the protrusion formed at the first oxide semiconductor pattern 474 will be referred to as a “first protrusion PP1”, and the protrusion formed at the upper buffer layer 445 will be referred to as a “second protrusion PP2”.

Since the first oxide semiconductor pattern 474 protrudes toward the second gate electrode 478, the second gate electrode 478 includes a first portion GP1 having a relatively small vertical distance from the first oxide semiconductor pattern 474, and a second portion GP2 having a relatively great vertical distance from the first oxide semiconductor pattern 474.

In connection with this structure, the first oxide semiconductor pattern 474 may include a first portion having a relatively small vertical distance from the second gate electrode 478, and a second portion having a relatively great vertical distance from the second gate electrode 478.

Referring to FIGS. 5A and 5B, the first protrusion PP1 and the second protrusion PP2 may have a quadrangular shape in a plan view. The quadrangular shape may have longitudinal sides extending in a longitudinal direction L of the second channel region 474C, and lateral sides extending in a width direction W of the second channel region 474C.

For reference, the longitudinal direction L of the second channel region 474C is defined as a direction extending from the second source electrode 479S to the second drain electrode 479D, and the width direction W of the second channel region 474C is defined as a direction intersecting the longitudinal direction L.

The thickness of a portion of the upper buffer layer 445 including the second protrusion PP2 may be greater than the thickness of a portion of the upper buffer layer 445 not including the second protrusion PP2.

On the other hand, the first oxide semiconductor pattern 474 may be deposited on the upper surface of the upper buffer layer 445 in a uniform thickness. Accordingly, the first semiconductor pattern 474 includes the first protrusion PP1 which protrudes from the second protrusion PP2 toward the second gate electrode 478.

When the first protrusion PP1 and the second protrusion PP2 have a rectangular shape, the lengths of the first protrusion PP1 and the second protrusion PP2 may be equal to or greater than the length of the second channel region 474C.

In addition, the widths of the first protrusion PP1 and the second protrusion PP2 are smaller than the width of the second channel region 474C and, as such, each of the first protrusion PP1 and the second protrusion PP2 may be disposed in a number of at least one in the width direction W of the second channel region 474C.

The second gate insulating layer 446 is deposited on the first oxide semiconductor pattern 474 and the upper buffer layer 445. In addition, the second gate electrode 478 is disposed on the second gate insulating layer 446. The second gate insulating layer 446 may be deposited to planarize steps by the upper surface of the upper buffer layer 445 formed with the first oxide semiconductor pattern 474. For Example, the second gate insulating layer 446 may be deposited such that an upper surface of the second gate insulating layer 446 is flat. Accordingly, the second gate insulating layer 446 may also be an organic layer.

Thus, the second gate electrode 478 includes both a first portion GP1 maintaining a first vertical distance D1 from the first oxide semiconductor pattern 474 and a second portion GP2 maintaining a second vertical distance D2 greater than the first vertical distance D1 from the first oxide semiconductor pattern 474.

That is, the first portion GP1 of the second gate electrode 478 is disposed near the first oxide semiconductor pattern 474 in a region corresponding to the first protrusion PP1, and the second portion GP2 of the second gate electrode 478 is disposed relatively far from the first oxide semiconductor pattern 474 in a region other than the first protrusion PP1.

The length of the second gate electrode 478 may be equal to the length of the second channel region 474C.

On the other hand, the length of the first protrusion PP1 may be equal to or greater than the length of the second gate electrode 478 and, as such, the second gate electrode 478 may be disposed over the first protrusion PP1 such that the entirety thereof is disposed over the first protrusion PP1.

Accordingly, on the first protrusion PP1, the first portion GP1 of the second gate electrode 478 maintains the first vertical distance D1 from the first oxide semiconductor pattern 474, and the second portion GP2 of the second gate electrode 478, except for the first protrusion PP1, maintains the second vertical distance D2 from the first oxide semiconductor pattern 474. Here, the first vertical distance D1 is smaller than the second vertical distance D2.

The third interlayer insulating layer 447 may be deposited on the second gate electrode 478. In addition, the second source electrode 479S and the second drain electrode 479D may be disposed on the third interlayer insulating layer 447.

Referring to FIG. 5A, the first portion GP1 of the second gate electrode 478 disposed on the first protrusion PP1, the second source electrode 479S and the second drain electrode 479D disposed at opposite sides of the second gate electrode 478, and the first oxide semiconductor pattern 474 may constitute a first sub-driving thin film transistor. In addition, the second portion GP2 of the second gate electrode 478, the second source electrode 479S, the second drain electrode 479D, and the first oxide semiconductor pattern 474 may constitute a second sub-driving thin film transistor.

That is, the driving thin film transistor DT may be regarded as having a configuration in which one first sub-driving thin film transistor disposed at a middle portion of the driving thin film transistor DT with reference to the first protrusion PP1 and two second sub-driving thin film transistors respectively disposed at opposite sides of the first sub-driving thin film transistor are connected in parallel.

Accordingly, the first sub-driving thin film transistor has a feature in that the first portion GP1 of the second gate electrode 478 maintains the first vertical distance D1 from the first oxide semiconductor pattern 474, and the second sub-driving thin film transistor has a feature in that the second portion GP2 of the second gate electrode 478 maintains the second vertical distance D2 from the first oxide semiconductor pattern 474.

In addition, the first sub-driving thin film transistor and the second sub-driving thin film transistor may be regarded as having a parallel connection structure in that the first sub-driving thin film transistor and the second sub-driving thin film transistor share the second gate electrode 478, the second source electrode 479S, and the second drain electrode 479D in common.

In addition, a first parasitic capacitance is formed between the first portion GP1 of the second gate electrode 478 functioning as a gate electrode of the first sub-driving thin film transistor and the first oxide semiconductor pattern 474, and a second parasitic capacitance smaller than the first parasitic capacitance is formed between the second portion GP2 of the second gate electrode 478 and the first oxide semiconductor pattern 474. As a result, the threshold voltage of the first sub-driving thin film transistor is lower than the threshold voltage of the second sub-driving thin film transistor. Thus, the first sub-driving thin film transistor turns on earlier than the second sub-driving thin film transistor at a low voltage and, as such, may take charge of grayscale expression of the driving thin film transistor at low gray levels.

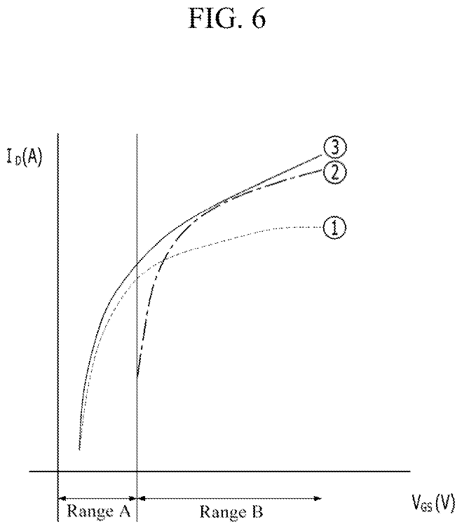

A V-I curve of the driving thin film transistor will be described with reference to FIG. 6. A curve \textcircled{1} of FIG. 6 represents a V-I curve of the first sub-driving thin film transistor which has a low threshold voltage. That is, the first sub-driving thin film transistor may turn on in a low voltage range because the threshold voltage thereof is relatively low and, as such, the driving thin film transistor may operate in a range A that is a low voltage range. This means that the driving thin film transistor turns on even at low gray levels.

On the other hand, a curve \textcircled{2} of FIG. 6 represents a V-I curve of the second sub-driving thin film transistor which has a relatively high threshold voltage. That is, the second sub-driving thin film transistor may turn on only when the voltage applied thereto reaches a range B that is a high voltage range, because the threshold voltage thereof is relatively high.

In addition, current flowing through the first sub-driving thin film transistor increases in synchronization with operation of the second sub-driving thin film transistor after the second sub-driving thin film transistor turns on. As a result, a synthetic current value may be represented as shown by a curve \textcircled{3} of FIG. 6.

Thus, the driving thin film transistor DT according to the aspect of the present disclosure may operate in a wide voltage range because the first sub-driving thin film transistor and the second sub-driving thin film transistor have a parallel connection configuration and, as such, may achieve grayscale expression in a wide voltage range. In particular, it may be possible to compensate for disadvantages of an oxide thin film transistor which has a difficulty in low-grayscale expression, even though it is advantageous in terms of blocking of leakage current when an oxide semiconductor pattern is used as an active layer.

Referring to FIG. 5A, the driving thin film transistor DT according to the aspect of the present disclosure may have a configuration including one first sub-driving thin film transistor disposed at a middle portion of the driving thin film transistor DT and two second sub-driving thin film transistors respectively disposed at opposite sides of the first sub-driving thin film transistor. However, this configuration is only illustrative, and the first sub-driving thin film transistor and the second sub-driving thin film transistor may be provided in plural such that plural first sub-driving thin film transistors and plural second sub-driving thin film transistors are arranged in the width direction of the second channel region.

Meanwhile, the structure of the driving thin film transistor DT will be described in more detail through cross-sectional views referring to FIGS. 5C to 5E.

FIG. 5C shows a portion of a cross-section of the driving thin film transistor DT taken along line E-E′ in FIG. 5A.

The upper buffer layer 445 includes the second protrusion PP2 at a portion thereof corresponding to the second channel region 474D. As the second oxide semiconductor pattern 474 is deposited on the upper buffer layer 445 including the second protrusion PP2, the second oxide semiconductor pattern 474 includes the first protrusion PP1. In addition, the first portion GP1 of the second gate electrode is disposed on the second oxide semiconductor pattern 474. The first portion GP1 of the second gate electrode and the first oxide semiconductor pattern 474 are spaced apart from each other by the first vertical distance D1. In addition, the thickness of the second gate insulating layer 446 corresponding to the second source region 474S and the second drain region 474D may correspond to the second vertical distance D2 greater than the first vertical thickness D1.

Meanwhile, FIG. 5D shows a portion of a cross-section of the driving thin film transistor DT taken along line F-F′ in FIG. 5A.

In FIG. 5D, the second portion GP2 of the second gate electrode is spaced apart from the second channel region 474D of the first oxide semiconductor pattern 474 by the second vertical distance D2. The second portion GP2 of the second gate electrode is disposed on the second gate insulating layer 446 in a region not overlapping with the first protrusion PP1.

FIG. 5E shows a portion of a cross-section of the driving thin film transistor DT taken along line G-G′ in FIG. 5A in the width direction of the second channel region 474C.

In FIG. 5E, the second channel region 474C extends in a width direction while including the first protrusion PP1, and the second gate electrode 478 is disposed on the second gate insulating layer 446 having a flat upper surface.

Meanwhile, referring to FIG. 4, the second source electrode 479S of the driving thin film transistor DT is electrically connected to the second light shielding pattern BSM-2. When the second light shielding pattern BSM-2 is electrically connected to the second source electrode 479S, the following additional effect may be obtained.

As the second source region 474S and the second drain region 474D of the first oxide semiconductor pattern 474 become conductive, a parasitic capacitance C_{act} is generated in the first oxide semiconductor pattern 474 in an on/off operation. In addition, a parasitic capacitance C_{gi} is generated between the second gate electrode 478 and the first oxide semiconductor pattern 474. In addition, a parasitic capacitance C_{buf} is generated between the second light shielding pattern BSM-2 electrically connected to the second source electrode 479S and the first oxide semiconductor pattern 474.

Since the first oxide semiconductor pattern 474 and the second light shielding pattern BSM-2 are electrically interconnected by the second source electrode 479S, the parasitic capacitance C_{act} and the parasitic capacitance C_{buf} are connected in parallel, and the parasitic capacitance C_{act} and the parasitic capacitance C_{gi} are connected in series. In addition, when a gate voltage of V_{gat} is applied to the second gate electrode 478, an effective voltage V_{eff} actually applied to the first oxide semiconductor pattern 474 satisfies the following Expression 1.

$${Δ V}_{eff} = \frac{{C}_{g i}}{{C}_{gi} + {C}_{buf} + {C}_{act}} * {ΔV}_{gat} \qquad [ Expression 1 ]$$

Thus, the effective voltage V_{eff} applied to the second channel region 474C is inversely proportional to the parasitic capacitance C_{buf} and, as such, it may be possible to adjust the effective voltage V_{eff} applied to the first oxide semiconductor pattern 474 by adjusting the parasitic capacitance C_{buf}.

That is, when the second light shielding pattern BSM-2 is disposed near the first oxide semiconductor pattern 474, to increase the parasitic capacitance C_{buf}, it may be possible to reduce an actual value of current flowing through the first oxide semiconductor pattern 474.

Reduction in the effective value of current flowing through the first oxide semiconductor pattern 474 means that an s-factor may be increased, and means that an actual control range of the driving thin film transistor DT controllable through the voltage V_{gat} applied to the second gate electrode 478 may be widened.

That is, when the second source electrode 479S of the driving thin film transistor DT is electrically connected to the second light shielding pattern BSM-2, and the second light shielding pattern BSM-2 is disposed near the first oxide semiconductor pattern 474, it may be possible to accurately control the organic light emitting element even at low gray levels and, as such, to solve a problem of a Mura defect frequently generated at low gray levels.

Accordingly, in the first aspect of the present disclosure, the parasitic capacitance C_{buf} generated between the first oxide semiconductor pattern 474 and the second light shielding pattern BSM-2 may be greater than the parasitic capacitance C_{gi} generated between the second gate electrode 478 and the first oxide semiconductor pattern 474.

Here, “s-factor” means a reciprocal value of a current variation to a gate voltage variation in an on/off transition period of a thin film transistor. That is, the s-factor may be a reciprocal value of a gradient of a curve in a characteristic graph of a drain current with respect to a gate voltage (V-I curve graph).

A small s-factor means a great gradient of a characteristic graph of a drain current with respect to a gate voltage. Accordingly, when a thin film transistor has a small s-factor, the thin film transistor may be turned on even by a low voltage and, as such, switching characteristics of the thin film transistor become better. However, sufficient grayscale expression is difficult because the thin film transistor reaches a threshold voltage within a short time.

A great s-factor means a small gradient of the characteristic graph of the drain current with respect to the gate voltage. Accordingly, when a thin film transistor has a great s-factor, the on/off response time of the thin film transistor may be degraded and, as such, switching characteristics of the thin film transistor may be degraded. However, sufficient grayscale expression may be possible because the thin film transistor reaches a threshold voltage after a relatively long time.

In particular, the second light shielding pattern BMS-2 may be disposed near the first oxide semiconductor pattern 474 while being embedded in the upper buffer layer 445. Of course, use of a plurality of sub-upper buffer layers is illustrated in the first aspect.

That is, the upper buffer layer 445 may have a structure in which a first sub-upper buffer layer 445a, a second sub-upper buffer layer 445b, and a third sub-upper buffer layer 445c are sequentially stacked. The second light shielding pattern BSM-2 may be formed over the first sub-upper buffer layer 445a. In addition, the second sub-upper buffer layer 445b completely covers the second light shielding pattern BSM-2. In addition, the third sub-upper buffer layer 45c is formed over the second sub-upper buffer layer 445b. This configuration is one example of a configuration in which the second light shielding pattern BSM-2 is embedded in the upper buffer layer 445.

The first sub-upper buffer layer 445a and the third sub-upper buffer layer 445c may be constituted by silicon oxide (SiO₂).

The first sub-upper buffer layer 445a and the third sub-upper buffer layer 445c are constituted by silicon oxide (SiO₂) not including hydrogen particles, thereby preventing hydrogen particles from penetrating into the oxide semiconductor pattern during heat treatment. When hydrogen particles penetrate into the oxide semiconductor pattern, reliability of the thin film transistor is degraded.

On the other hand, the second sub-upper buffer layer 445b may be constituted by silicon nitride (SiNₓ) having an excellent hydrogen particle collection ability.

Meanwhile, although not shown in FIG. 4, the second sub-upper buffer layer 445b may be formed only in a region where the second light shielding pattern BSM-2 is formed to completely encapsulate the second light shielding pattern BSM-2. That is, the second sub-upper buffer layer 445b of a silicon nitride (SiNₓ) layer may be partially formed on the first sub-upper buffer layer 445a to completely cover an upper surface and a side surface of the second light shielding pattern BSM-2.

In addition, as shown in FIG. 4, the second sub-upper buffer layer 445b may be formed over the entire surface on the first sub-upper buffer layer 445a formed with the second light shielding pattern BSM-2.

Silicon nitride (SiNₓ) is excellent in terms of hydrogen particle collection ability, as compared to silicon oxide (SiO₂). When hydrogen particles penetrate into an active layer constituted by an oxide semiconductor material, resultant thin film transistors may have a problem in that the thin film transistors have different threshold voltages or different conductivities at channels thereof. That is, reliability of the thin film transistors is degraded. In particular, in the case of a driving thin film transistor, securing reliability is important because the driving thin film transistor directly contributes to operation of the light emitting element associated therewith.

Accordingly, it may be possible to prevent degradation in reliability of the driving thin film transistor DT caused by hydrogen particles by partially or completely forming the second sub-upper buffer layer 445b covering the second light shielding pattern BSM-2 over the first sub-upper buffer layer 445a.

When the second sub-upper buffer layer 445b is partially deposited on the first sub-upper buffer layer 445a, there is an advantage as follows.

That is, since the second sub-upper buffer layer 445b is formed of a material different from that of the first sub-upper buffer layer 445a, layer blister may occur between the heterogeneous material layers when the second sub-upper buffer layer 445b is deposited over the entire surface of the active area. To solve such a problem, the second sub-upper buffer layer 445b may be selectively formed only in a region where the second light shielding pattern BSM-2 is formed, for an enhancement in bonding force.

The second light shielding pattern BSM-2 may be formed vertically under the first oxide semiconductor pattern 474, to overlap with the first oxide semiconductor pattern 474. In addition, the second light shielding pattern BSM-2 may be formed to have a size greater than that of the first oxide semiconductor pattern 474, to completely overlap with the first oxide semiconductor pattern 474.

The second light shielding pattern BSM-2 may be disposed near the first oxide semiconductor pattern 474, thereby increasing the parasitic capacitance generated between the first oxide semiconductor pattern 474 and the second light shielding pattern BSM-2. In this case, the s-factor of the driving thin film transistor DT is increased and, as such, the driving thin film transistor DT may additionally achieve grayscale expression even at low gray levels.

Meanwhile, the second gate electrode 478 of the driving thin film transistor DT is insulated by the third interlayer insulating layer 447. The second source electrode 479S and the second drain electrode 479D are formed on the third interlayer insulating layer 447.

Although the second source electrode 479S and the second drain electrode 479D are shown as being disposed on the same layer, and the second gate electrode 478 is shown as being formed on a layer different from that of the second source electrode 479S and the second drain electrode 479D in the first aspect of the present disclosure referring to FIG. 4, all of the second gate electrode 478, the second source electrode 479S, and the second drain electrode 479D may be disposed on the same layer.

The second source electrode 479S and the second drain electrode 479D are connected to the second source region 474S and the second drain region 474D via a third contact hole CH3 and a fourth contact hole CH4, respectively. In addition, the second light shielding pattern BSM-2 is connected to the second source electrode 479S via a fifth contact hole CH5.

Meanwhile, the first switching thin film transistor ST-1 includes a second oxide semiconductor pattern 432, a third gate electrode 433, a third source electrode 434S, and a third drain electrode 434D.

The second oxide semiconductor pattern 432 includes a third channel region 432C, and a third source region 432S and a third drain region 432D disposed adjacent to the third channel region 432C under the condition that the third channel region 432C is interposed therebetween.

The third gate electrode 433 is disposed over the second oxide semiconductor pattern 432 under the condition that the second gate insulating layer 446 is interposed therebetween.

The third source electrode 434S and the third drain electrode 434D may be disposed on the same layer as the second source electrode 479S and the second drain electrode 479D. That is, the second source/drain electrodes 479S and 479D and the third source/drain electrodes 434S and 434D may be disposed on the third interlayer insulating layer 447.

Of course, the third source/drain electrodes 434S and 434D may be disposed on the same layer as the third gate electrode 433. That is, the third source/drain electrodes 434S and 434D may be formed on the second gate insulating layer 446 simultaneously with the third gate electrode 433, using the same material as that of the third gate electrode 433.

In addition, a third light shielding pattern BSM-3 may be disposed under the second oxide semiconductor pattern 432. The third light shielding pattern BSM-3 may be formed over the first gate insulating layer 442, together with the first gate electrode 416.

The third gate electrode 433 and the third light shielding pattern BSM-3 may be electrically interconnected, thereby constituting a dual gate.

Meanwhile, referring to FIG. 4, the sub-pixel includes a storage capacitor Cst.

The storage capacitor Cst stores a data voltage applied thereto via a data line for a predetermined period, and then provides the stored data voltage to the organic light emitting element.

The storage capacitor Cst includes two electrodes corresponding to each other, and a dielectric disposed between the two electrodes. The storage capacitor Cst includes a first electrode 450A disposed on the same layer as the first gate electrode 416 and made of the same material as that of the first gate electrode 416, and a second electrode 450B facing the first electrode 450A while overlapping with the first electrode 450A.

The first interlayer insulating layer 443 may be interposed between the first electrode 450A and the second electrode 450B of the storage capacitor Cst.

The second electrode 450B of the storage capacitor Cst may be electrically connected to the second source electrode 479S via a tenth contact hole CH10.

In addition, there may be an advantage in that mask processes are reduced because the first electrode 450A of the storage capacitor Cst is formed on the same layer as the first gate electrode 416 and the second light shielding pattern BSM-2.

Meanwhile, referring to FIG. 4, a first planarization layer PLN1 may be formed over the substrate 410 on which the driving thin film transistor DT and the first switching thin film transistor ST-1 are disposed. Although the first planarization layer PLN1 may be formed of an organic material such as photoacryl, the first planarization layer PLN1 may also be constituted by a plurality of layers constituted by an inorganic layer and an organic layer. A connection electrode 455 is formed over the first planarization layer PLN1. The connection electrode 455 electrically interconnects an anode 456, which is one constituent element of a light emitting device part 460, and the driving thin film transistor DT via an eighth contact hole CH8 formed in the first planarization layer PLN1.

In addition, a conductive layer used to form the connection electrode 455 may constitute a part of various link lines disposed in a bending area BA.

A second planarization layer PLN2 may be formed over the connection electrode 455. Although the second planarization layer PLN2 may be formed of an organic material such as photoacryl, the second planarization layer PLN2 may also be constituted by a plurality of layers constituted by an inorganic layer and an organic layer.

The anode 456 is formed over the second planarization layer PLN2. The anode 456 is electrically connected to the connection electrode 455 via a ninth contact hole CH9 formed in the second planarization layer PLN2.

The anode 456 may take the form of a single layer or multiple layers made of a metal such as Ca, Ba, Mg, Al, Ag, etc. or an alloy thereof. The anode 456 is connected to the second drain electrode 479D of the driving thin film transistor DT and, as such, an image signal from the outside is applied thereto.

In addition to the anode 456, an anode connection electrode 457, which electrically interconnects a common voltage line VSS and a cathode 463, may be further provided in a non-active area NA.

A bank layer 461 is formed over the second planarization layer PLN2. The bank layer 461 is a kind of barrier, and may partition sub-pixels, thereby preventing light of particular colors output from adjacent ones of the sub-pixels from being output in a mixed state.

An organic light emitting layer 462 is formed on a surface of the anode 456 and a portion of an inclined surface of the bank layer 461. The organic light emitting layer 462 may be an R-organic light emitting layer configured to emit red light, a G-organic light emitting layer configured to emit green light, or a B-organic light emitting layer configured to emit blue light, which is formed at each sub-pixel. In addition, the organic light emitting layer 462 may be a W-organic light emitting layer configured to emit white light.

The organic light emitting layer 462 may include not only a light emitting layer, but also an electron injection layer and a hole injection layer respectively configured to inject electrons and holes into the light emitting layer, an electron transportation layer and a hole transportation layer respectively configured to transport injected electrons and holes to an organic layer, etc.

The cathode 463 is formed over the organic light emitting layer 462. The cathode 463 may be made of a transparent conductive material such as indium tin oxide (ITO) or indium zinc oxide (IZO), or a thin metal allowing transmission of visible light therethrough, without being limited thereto.

An encapsulation layer part 470 is formed over the cathode 463. The encapsulation layer part 470 may be constituted by a single layer formed of an inorganic layer, a double layer of inorganic layer/organic layer, or a triple layer of inorganic layer/organic layer/inorganic layer. The inorganic layer may be constituted by an inorganic material such as SiNₓ, SiX, or the like, without being limited thereto. In addition, the organic layer may be constituted by an organic material such as polyethylene terephthalate, polyethylene naphthalate, polycarbonate, polyimide, polyethylene sulfonate, polyoxymethylene, polyarylate, etc., or a mixture thereof, without being limited thereto.

In FIG. 4, an aspect of the encapsulation layer part 470 is illustrated as being constituted by a triple layer of inorganic layer 471/organic layer 472/inorganic layer 473.

A cover glass (not shown) may be disposed over the encapsulation layer part 470, and may be attached to the encapsulation layer part 470 by an adhesive layer (not shown). Although any material may be used as the adhesive layer, so long as the material exhibits excellent attachment force while being excellent in terms of heat resistance and water resistance, a thermosetting resin such as an epoxy-based compound, an acrylate-based compound, or an acryl-based rubber may be used in the present disclosure. Alternatively, a photo-curable resin may be used as the adhesive. In this case, the adhesive layer is cured through irradiation of the adhesive layer with light such as ultraviolet light.

The adhesive layer may not only serve to assemble the substrate 410 and the cover glass (not shown), but also to function as an encapsulator for preventing penetration of moisture into an interior of the display device which may be an organic electroluminescent display device.

The cover glass (not shown) may be an encapsulation cap for encapsulating the organic electroluminescent display device, and may use a protective film such as a polystyrene (PS) film, a polyethylene (PE) film, a polyethylene naphthalate (PEN) film, a polyimide (PI) film, or the like, and may use glass.

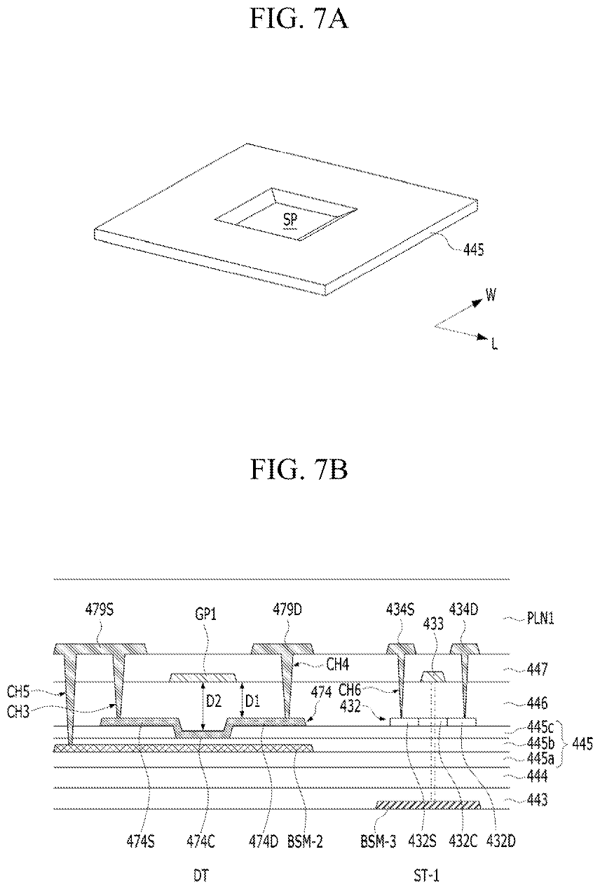

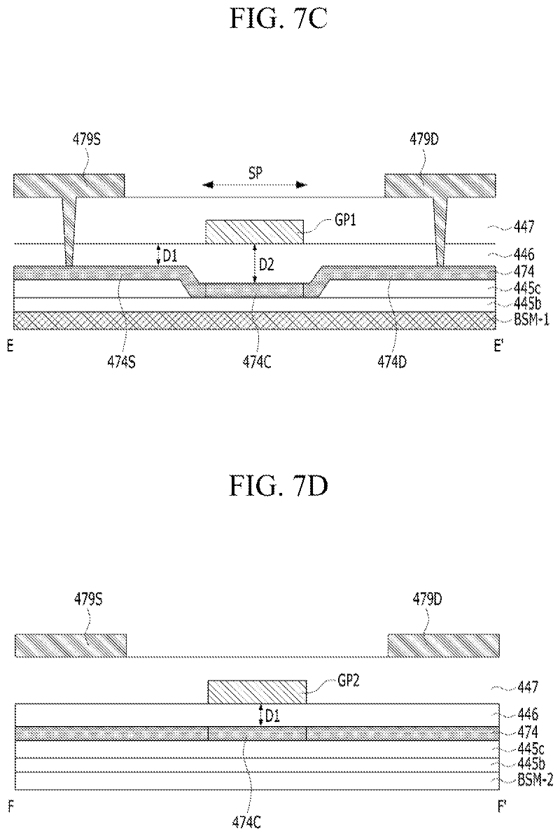

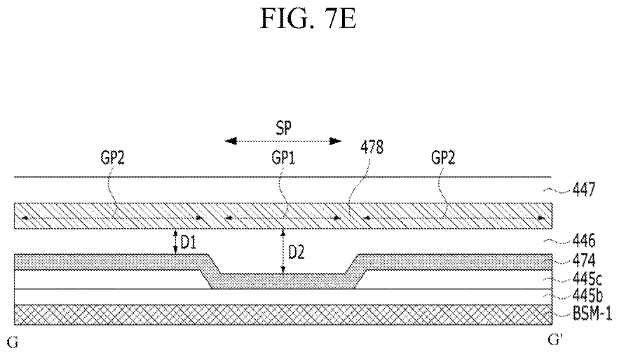

Hereinafter, another aspect of the present disclosure will be described with reference to FIGS. 7A to 7E.

In the first aspect of the present disclosure, it has been described that the sub-thin film transistor may have a configuration in which the upper buffer layer 445 and the first semiconductor pattern 474 deposited thereon include protrusions, respectively, and, as such, the first oxide semiconductor pattern 474 and the second gate electrode 478 have different vertical distances, respectively.

In association with a second aspect of the present disclosure, the case in which a sub-thin film transistor is configured such that an upper buffer layer 445 includes a sink SP and, as such, a first oxide semiconductor pattern 474 and a second gate electrode 478 have different vertical distances, respectively, will be described.

The following description will be given with reference to FIGS. 7A to 7E, and a description overlapping with that of the first aspect will be omitted.

In the second aspect, the upper buffer layer 445 includes the sink SP such that each of the first oxide semiconductor pattern 474 formed on the upper buffer layer 445 and the second gate electrode 478 disposed over the first oxide semiconductor pattern 474 includes at least two regions respectively having different vertical distances.

For convenience of description, the sink SP may be disposed at the same position as that of the protrusion PP2 disposed at the buffer layer 445 in the first aspect. Accordingly, lines E-E′, F-F′, and G-G′ are the same as those of FIG. 5A.

As the sink SP is disposed at the same position as that of the protrusion PP2 of the first aspect, in a driving thin film transistor DT of the second aspect, a second sub-driving thin film transistor in which the distance between the second oxide semiconductor pattern 474 and the second gate electrode 478 is a second vertical distance D2 is disposed at a central portion of a second channel region 474C. In addition, first sub-driving thin film transistors in which the distance between the second oxide semiconductor pattern 474 and the second gate electrode 478 is a first vertical distance D1 are disposed at opposite sides of the sink SP in a width direction of the second channel region 474, respectively. The first vertical distance D1 is smaller than the second vertical distance D2.

In the second aspect, accordingly, the driving thin film transistor DT has a configuration in which two first sub-driving thin film transistors having a relatively low threshold voltage are disposed at opposite sides of the sink SP, respectively, and one second sub-driving thin film transistor having a relatively high threshold voltage is disposed between the first sub-driving thin film transistors. The first sub-driving thin film transistors and the second sub-driving thin film transistor are configured to be interconnected in parallel.

Accordingly, similarly to the first aspect described with reference to FIG. 4, the first sub-driving thin film transistors may turn on in a low voltage range, that is, the range A, because the threshold voltage thereof is relatively low, and the second sub-driving thin film transistor may turn on in a high voltage range, that is, the range B, because the threshold voltage thereof is relatively high. Accordingly, the driving thin film transistor DT may have a wide grayscale expression range.

FIG. 7B is an enlarged cross-sectional view of portions of the driving thin film transistor DT and a first switching thin film transistor ST-1 according to the second aspect. The cross-sectional structure of the first switching thin film transistor ST-1 is identical to that of the first aspect, and the driving thin film transistor DT is identical to that of the first aspect, except that the first oxide semiconductor pattern 474 includes the sink SP at a central portion thereof.

FIG. 7C is a cross-sectional view of a portion of the driving thin film transistor DT taken along line E-E′.

A first portion GP1 of the second gate electrode is disposed to be spaced apart from the first oxide semiconductor pattern 474 formed at the sink SP by the second vertical distance D2.

Referring to FIG. 7D, a second portion GP2 of the second gate electrode is disposed to be spaced apart from the first oxide semiconductor pattern 474 by the first vertical distance D1.

Referring to FIG. 7E taken in the width direction of the second channel region 474C, it may be seen that each of the second oxide semiconductor pattern 474 and the second gate electrode 478 includes both a portion spaced by the first vertical distance D1 and a portion spaced by the second vertical distance D2.

Although FIGS. 7A to 7E have described the case in which only one sink SP is formed in the second channel region 474C, the sink SP may be formed in plural in the width direction of the second channel region 474C.

As apparent from the above description, in accordance with exemplary aspects of the present disclosure, a pixel includes a driving thin film transistor and a switching thin film transistor, which include oxide semiconductor patterns, thereby blocking leakage current in an off state. Accordingly, a reduction in power consumption may be achieved.

Although it is difficult to adjust a threshold voltage due to characteristics of an oxide semiconductor material, it may be possible to provide a driving thin film transistor having a threshold voltage adjusted to achieve grayscale expression within a wide range while using the oxide semiconductor material as an active layer thereof in accordance with exemplary aspects of the present disclosure.

In addition, the driving thin film transistor may provide a structure capable of increasing an s-factor value and, as such, a thin film transistor array substrate capable of achieving free grayscale expression at low gray levels may be provided.

Effects of the present disclosure are not limited to the above-described effects. Other effects not described in the present disclosure may be readily understood by those skilled in the art from the appended claims.

It will be appreciated that the technical spirit of the present disclosure has been described herein only for purposes of illustration through the above description and the accompanying drawings, and that combination, separation, substitution, and modifications of components may be made by those skilled in the art without departing from the scope and spirit of the present disclosure. Therefore, the exemplary aspects of the present disclosure are provided for illustrative purposes only and are not intended to limit the technical spirit of the present disclosure. The scope of the technical spirit of the present disclosure is not limited thereto. The protection scope of the present disclosure should be interpreted based on the appended claims, and it should be appreciated that all technical ideas falling within a range equivalent to the claims are included in the protection scope of the present disclosure.

What is claimed is:

1. A thin film transistor array substrate comprising:
a substrate comprising an active area and a non-active area disposed around the active area;
a first thin film transistor disposed on the substrate; and,
a first light shielding pattern disposed between the substrate and the first thin film transistor,
wherein the first thin film transistor comprises a first oxide semiconductor pattern disposed on the substrate, a first gate electrode, a first gate insulating layer interposed between the first oxide semiconductor pattern and the first gate electrode, a first source electrode, and a first drain electrode,
wherein the first light shielding pattern is electrically connected to one of the first source electrode and the first drain electrode and is disposed under the first oxide semiconductor pattern,
wherein the first oxide semiconductor pattern comprises a first portion configured to form a first parasitic capacitance, together with the first gate electrode, and a second portion configured to form a second parasitic capacitance, together with the first gate electrode, and
wherein the first parasitic capacitance and the second parasitic capacitance are different from each other.

2. The thin film transistor array substrate according to claim 1, wherein the first portion of the first oxide semiconductor pattern comprises a first protrusion protruding toward the first gate electrode.

3. The thin film transistor array substrate according to claim 2, wherein the first oxide semiconductor pattern comprises:
a first source region connected to the first source electrode,
a first drain region connected to the first drain electrode, and
a first channel region disposed between the first source region and the first drain region,
wherein a length of the first protrusion is equal to or greater than a length of the first channel region.

4. The thin film transistor array substrate according to claim 3, wherein the first protrusion of the first oxide semiconductor pattern corresponds to the first channel region.

5. The thin film transistor array substrate according to claim 3, wherein the first protrusion is disposed in a number of at least one in a width direction of the first channel region.

6. The thin film transistor array substrate according to claim 2, wherein the first parasitic capacitance is greater than the second parasitic capacitance.

7. The thin film transistor array substrate according to claim 2, further comprising:
a buffer layer between the first oxide semiconductor pattern and the first light shielding pattern,
wherein the buffer layer comprises a second protrusion protruding toward the first gate electrode, and
wherein the first protrusion of the first oxide semiconductor pattern is deposited along a curvature of an upper surface of the buffer layer.

8. The thin film transistor array substrate according to claim 2, wherein, when a vertical distance from the first protrusion to the first gate electrode is a first vertical distance (D1), and a vertical distance from the first oxide semiconductor pattern, except for the first protrusion, to the first gate electrode is a second vertical distance (D2), the second vertical distance (D2) is greater than the first vertical distance (D1).

9. The thin film transistor array substrate according to claim 1, wherein the first portion of the first oxide semiconductor pattern comprises a first sink recessed to be spaced away from the first gate electrode.

10. The thin film transistor array substrate according to claim 9, wherein the first oxide semiconductor pattern comprises a first source region connected to the first source electrode, a first drain region connected to the first drain electrode, and a first channel region disposed between the first source region and the first drain region; and
wherein a length of the first sink is equal to or greater than a length of the first channel region.

11. The thin film transistor array substrate according to claim 10, wherein the first sink of the first oxide semiconductor pattern corresponds to the first channel region.

12. The thin film transistor array substrate according to claim 10, wherein the first sink is disposed in a number of at least one in a width direction of the first channel region.

13. The thin film transistor array substrate according to claim 9, wherein the second parasitic capacitance is greater than the first parasitic capacitance.

14. The thin film transistor array substrate according to claim 9, further comprising:
a buffer layer between the first oxide semiconductor pattern and the first light shielding pattern,
wherein the buffer layer comprises a second sink recessed to be spaced away from the first gate electrode, and
wherein the first sink of the first oxide semiconductor pattern is deposited along a curvature of an upper surface of the buffer layer.

15. The thin film transistor array substrate according to claim 9, wherein, when a vertical distance from the first sink to the first gate electrode is a second vertical distance (D2), and a vertical distance from the first oxide semiconductor pattern, except for the first sink, to the first gate electrode is a first vertical distance (D1), the second vertical distance (D2) is greater than the first vertical distance (D1).

16. The thin film transistor array substrate according to claim 1, wherein the first thin film transistor is a driving thin film transistor configured to drive a pixel disposed in the active area.

17. The thin film transistor array substrate according to claim 1, wherein a parasitic capacitance formed between the first light shielding pattern and the first oxide semiconductor pattern is greater than a parasitic capacitance formed between the first gate electrode and the first oxide semiconductor pattern.

18. The thin film transistor array substrate according to claim 1, wherein the first thin film transistor comprises a first sub-first thin film transistor and a second sub-first thin film transistor;
the first sub-first thin film transistor comprises the first portion of the first oxide semiconductor pattern, the first gate electrode, the first source electrode, and the first drain electrode;
the second sub-first thin film transistor comprises the second portion of the first oxide semiconductor pattern, the first gate electrode, the first source electrode, and the first drain electrode; and
wherein a threshold voltage of the first sub-first thin film transistor is different from a threshold voltage of the second sub-first thin film transistor.

19. A display device comprising:
the thin film transistor array substrate according to claim 1; and
a light emitting device part disposed on the substrate, the light emitting device part comprising a first electrode connected to the first drain electrode, a second electrode corresponding to the first electrode, and a light emitting layer disposed between the first electrode and the second electrode.
